(19) United States
(12) Patent Application Publication
(10) Pub. No.: US 2011/0018623 A1
(43) Pub. Date: Jan. 27, 2011

(54) INTEGRATED CIRCUIT PACKAGE

(76) Inventors: Grant M. More, Edinburgh (GB); Holger Halplik, Swindon (GB); Abhay Kejriwal, Swindon (GB)

Correspondence Address: DICKSTEIN SHAPIRO LLP, 1825 EYE STREET NW, Washington, DC, 20006-5403, US

(21) Appl. No.: 12/841,629

(22) Filed: Jul. 22, 2010

Related U.S. Application Data
(60) Provisional application No. 61/227,973, filed on Jul. 23, 2009.

(30) Foreign Application Priority Data
Jul. 22, 2009 (GB) 0912691.3

(51) Int. Cl. H01L 25/00

(52) U.S. Cl. 327/564

(57) ABSTRACT

An integrated circuit combination, comprising first and second integrated circuit dies with respective first and second control register banks, and a path for external control data, within said combination, coupling a first data interface on said first die, which receives the external control data, to the first and second control register banks.

This application claims the benefit of U.S. Provisional Application No. 61/227,973, filed Jul. 23, 2009.

### BACKGROUND OF THE INVENTION

1. Field of the Invention

The present invention relates to integrated circuits, and particularly to an integrated circuit combination comprising two or more integrated circuit dies.

2. Description of the Related Art

Designers of electronic products or devices, such as mobile phones, MP3 players, games consoles, PCs, televisions sets, etc, desire to reduce part count and hence reduce physical size and product assembly cost. They thus desire to integrate multiple diverse functions into single packages.

Designers of end products would also like to use single integrated circuits (ICs) with multiple, diverse functionalities. For example, if two or more ICs having two or more separate functions can be replaced by a single IC which performs both of these functions, there are potentially cost and size benefits to the end-product designer. However, an IC that is designed to fulfil two functions may generally perform those functions less well or less economically than two dedicated ICs. This may be for logistical reasons, in that advances in circuit design are more likely to be tried first on dedicated chips designed by specialist engineers, rather than on larger chips comprising mainly generally available circuit blocks. More fundamentally it may be because dedicated chips may be designed using the most appropriate process in terms of minimum feature size and voltage rating and special device structures for voltage or high-frequency performance.

One solution to the above problem is to provide the required set of functions using two or more ICs in a single IC package, also known as a system-in-package (SiP). This technique also offers side benefits. For instance a range of combinations of IC pairs can be offered on a “mix-and-match” basis. That is, a common power management IC can be paired with audio codecs of different performance levels, or differentiated power ICs for different equipment power schemes can be paired with the same audio codec. This increases the range of markets serviced by the SiP family. Also for more specialist applications, the component ICs may be sold as separately packaged devices. Thus the design costs can be amortized over a wider range of customers. Also component ICs can be cost-reduced by redesign to eliminate superfluous functions or by transfer to a smaller feature size process, without having to repeat the redesign over a whole family of silicon die.

SiPs are known in the art and in one format comprise a processor and a single “slave” IC coupled to the processor. For example, U.S. Pat. No. 7,247,930 discloses a central processing unit (CPU) die bonded to a power management die in a three-dimensional packaging layout. The provision of a processing die as one of the ICs in the SiP effectively “hides” the power management die, in that a CPU will ordinarily communicate with a power management IC regardless of whether the power management die is in the same package as the CPU or not. The power management die generally does not communicate with any other ICs except the CPU, and so the provision of the power management die in the same package as the CPU merely reduces the footprint of the combination of the CPU and the power management die.

SiPs are also known in which two ICs are provided, but in which each IC is separately connected to circuitry outside the package. Again, these SiPs reduce the footprint of a combination of two ICs, and provide a convenient delivery mechanism for two ICs. However, each IC must be separately connected via pins to external circuitry.

### SUMMARY OF THE INVENTION

The present invention provides an integrated circuit combination, comprising first and second integrated circuit dies with respective first and second control register banks, and a path for external control data, within said combination, coupling a first data interface on said first die, which receives the external control data, to the first and second control register banks.

In particular, according to a first aspect of the invention, there is provided an integrated circuit combination, or system-in-package (SiP), comprising: a first integrated circuit die comprising at least a first interface for at least receiving control signals, a second interface and a first control register bank; a second integrated circuit die comprising at least a third interface, coupled to said second interface, and a second control register bank; and a signal path, within said combination, coupling said first interface to said first control register bank and to said second control register bank via said second and third interfaces.

The invention therefore provides an integrated circuit combination comprising two or more integrated circuit dies arranged such that a controller or processor, in communication with the combination, “sees” only a single device, for example having a single device address. This substantially reduces the number of pins on the processor required to communicate with the combination.

In a second aspect, the present invention provides a method in an integrated circuit die. The integrated circuit die is connected to a further integrated circuit die as part of an integrated circuit combination. The method comprises: receiving a control signal; and forwarding the control signal to the further integrated circuit die regardless of whether or not the control signal was intended for the further integrated circuit die.

### BRIEF DESCRIPTION OF THE DRAWINGS

For a better understanding of the present invention, and to show more clearly how it may be carried into effect, reference will now be made, by way of example, to the following drawings, in which:

FIG. 1 shows an apparatus comprising an integrated circuit combination according to the present invention;

FIG. 2 shows in greater detail an apparatus comprising an integrated circuit combination according to embodiments of the present invention;

FIG. 3 shows a mapping for registers according to a first embodiment of the present invention;

FIG. 4 shows a mapping for registers according to a second embodiment of the present invention;

FIG. 5 shows an arrangement in a SiP according to an embodiment of the present invention;

FIG. 6 shows another arrangement in a SiP according to an embodiment of the present invention;

FIG. 7 shows a further arrangement in a SiP according to an embodiment of the present invention; and

FIG. 8 is a flowchart of a method according to embodiments of the present invention.

### DETAILED DESCRIPTION

The present invention provides a combination (also referred to herein as a system-in-package, or SiP) comprising two or more IC dies. The first IC die further comprises an interface to external circuitry, through which all signals to the first and second IC dies are routed.

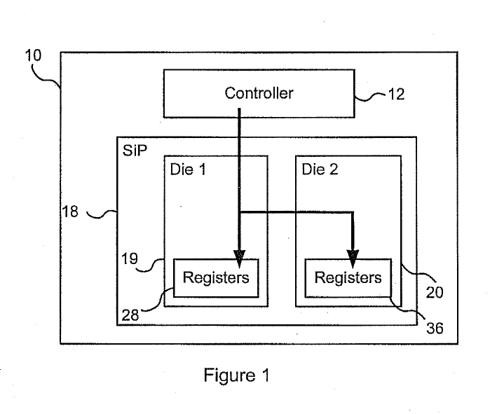

FIG. 1 shows an example of an apparatus 10 comprising a SiP 18 according to embodiments of the present invention.

The apparatus 10 may be a portable electronic device, for example a computing device; a laptop; a notebook computer; a PDA; a media player; an MP3 player; a video player; a portable television device; a communication device; a mobile telephone; a mobile email device; a GPS device or a navigation device.

The apparatus 10 comprises a controller 12, for example a processor, and a SiP 18 coupled to the controller 12. The SiP 18 itself comprises two integrated circuit (IC) dies: a first, “parent” IC die 19 and a second, “child” IC die 20. Each of the IC dies 19, provides specialized functionality beyond that which would normally be provided by the controller 12. For example, the IC dies 19, 20 may be individually dedicated to power management, audio coding/decoding, video coding/decoding, encryption, or any function that is better provided by a dedicated IC than the controller 12.

The IC dies 19, 20 each receive signals from the controller 12 in order to provide at least part of their functionality. Signals from the controller 12 are routed through the parent IC die 19; this occurs regardless of whether the signals are intended for the parent IC die 19 or the child IC die 20. The parent IC die 19 receives and forwards signals from the controller 12 to the child IC die 20, as will be described in greater detail below.

The IC dies 19, 20 may have a set of controllable features such as programmable output voltage levels, signal path routing, and enabling and disabling circuit blocks, etc. These are configurable via on-chip registers storing digital control data, either as a physically contiguous bank of registers or as a bank of registers scattered across the chip close to the blocks involved. Thus, the parent IC die 19 comprises a bank of registers 28 and the child IC die 20 comprises a bank of registers 36. These registers 28, 36 are programmed by control signals received from the controller 12 that manages the host apparatus 10. Each register on a chip has a register address, and the incoming control signals contain this address as well as the control data to be written to the register with that address.

Signals from the controller 12 therefore have at least a register address part and may also have a device address part (i.e. addressing a particular IC component of the apparatus 10) depending on the protocol in use. This allows control signals, etc, to be correctly routed to the desired device, and then to the desired register address of that device. According to embodiments of the present invention, to be described in greater detail below, the SiP 18 has a single device address that allows signals to the SiP to be routed to either the parent die 19 or the child die 20. That is, the controller 12 “sees” only a single device to which it sends signals, rather than the two IC dies 19, 20 individually.

According to embodiments of the present invention, therefore, it is the parent IC die 19 which is configured to forward signals to the child IC die 20. In these embodiments the “forwarding” functionality, and the corresponding circuitry to perform that function, all lie within the parent IC die 19. This allows the child IC die 20 to be substantially conventional, i.e. to be substantially the same as if it were not part of an SiP, and were communicating directly with the controller 12.

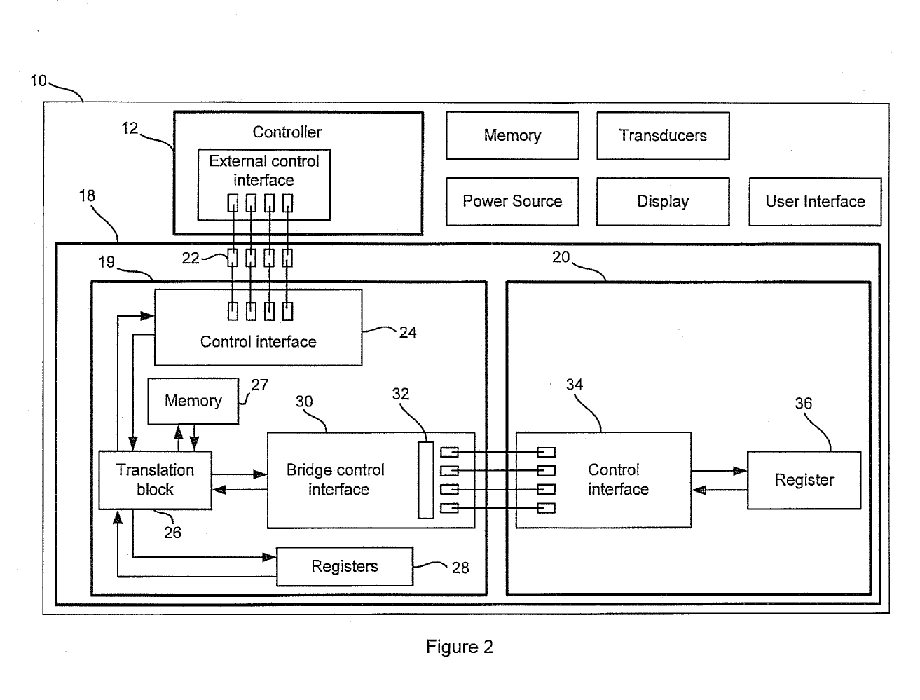

FIG. 2 shows in more detail an apparatus 10 comprising a SiP 18 according to embodiments of the invention.

The apparatus 10 may be any electronic apparatus, and as such may comprise a number of different electronic components. The apparatus 10 comprises a controller 12, which may be a processor (i.e. a central processing unit) or a less powerful controlling component. The controller 12 may act as a bus master to the other components, although those other components may also act as bus masters in certain communications. Thus, the apparatus 10 may comprise, for example, a memory, at least one power source, a display (or drivers for the display), one or more transducers such as microphones or loudspeakers, a user interface, etc. The respective connections of these components are not important to an understanding of the invention, so they are not illustrated for clarity.

In addition, according to embodiments of the present invention, the apparatus 10 further comprises a combination of integrated circuits 18, also known as a SiP. As described above, the SiP 18 comprises a parent IC die 19 and a child IC die 20, and each of these dies may perform a specific function. For example, the parent IC die 19 may be a power management IC, and the child IC die 20 may be an audio codec.

The controller 12 comprises an external control interface through which signals are sent to the SiP 18, as well as the other electrical components (not illustrated).

In the illustrated embodiment, the SiP 18 comprises a set of bond pads 22 connected to the external control interface, and the parent IC die 19 comprises a control interface 24 that is coupled to the bond pads 22. The parent IC die 19 further comprises a translation block 26 coupled to the control interface 24. A bank of registers 28 is coupled to the translation block 26. The registers 28 store digital control data, either as a physically contiguous bank of registers or as a bank of registers scattered across the parent IC die 19 close to the blocks involved. Further circuitry related to the function of the parent IC die 19 (e.g. audio codec circuitry, encryption circuitry, etc) is not illustrated here for the purposes of clarity. The parent IC die 19 may comprise a memory 27 to which the translation block has access to configure its operation. The memory 27 may be a ROM or a set of metal masked connections to a register, or may be electrically programmable. In the latter case it may be non-volatile memory such as metal or polysilicon fuses or a one-time-programmable (OTP) array. It may also be reprogrammable memory such as EEPROM or Flash memory. The memory may be programmed as part of the die-level manufacturing test, or may be programmed later, once assembled into the SiP 18.

The parent IC die 19 further comprises a bridge control interface 30 coupled to the translation block 26. The bridge control interface 30 may comprise level shift circuitry 32, as well as a connection to the child IC die 20.

The child IC die 20 comprises its own control interface 34, connected to receive signals from the bridge control interface 30. Coupled to the control interface 34 is a bank of registers 36 of the child IC die 20. The registers 36 store digital control data, either as a physically contiguous bank of registers or as a bank of registers scattered across the child IC die 20 close to the blocks involved. As with the parent IC die 19, further circuitry related to the function of the child IC die 20 is not illustrated here for the purposes of clarity.

In operation of the SiP 18, control signals are received from the external control bus of the controller 12 over the bond pads 22, and passed to the control interface 24 of the parent IC die 19.

In one embodiment, the external control interface communicates with the control interface 24 using an I²C (inter IC) bus; however, according to other embodiments of the present invention, JTAG (Joint Test Action Group), SRI (serial peripheral interface), or any other buses may also be used. Depending on the bus protocol, the signals may comprise different fields and information. For example, signals sent using the I²C bus protocol have a device address part and a register address part, as well as a data part. Signals sent using the SRI protocol have a register address part and a data part only. The device is addressed in this protocol by use of a chip select (CS) line for each destination chip.

In certain embodiments, the control signals are then passed from the control interface 24 to the translation block 26. The function of the translation block 26 depends on the particular embodiment of the invention, to be described in greater detail below. In some embodiments the translation block 26 may not be necessary at all.

In embodiments employing a bus protocol with a device address part (e.g. I²C), the translation block 26 performs device address translation on the received control signal. That is, the SiP 18 has its own unique device address with which incoming signals are labelled, that is, the external device only sees a single entity at the SiP's location.

However, the parent IC die 19 and the child IC die 20 also have unique device addresses, which enable them to be used individually in other devices (i.e. when not employed as part of a SiP). The translation block 26 accesses the memory 27, in which is stored the unique device address of the child IC die 20, and replaces the SiP address in the control signal with the device address of the child IC die.

Of course, in embodiments employing a bus protocol without a device address part (e.g. SPI), no device address translation takes place. In this case there may be a single CS line for the whole SiP, since the destination register is defined by the register address part of the signal, as will be described in greater detail below.

The translation block 26 may further determine whether the received control signal is intended for the parent IC die 19 or the child IC die 20, based on the content of the register address part of the control signal.

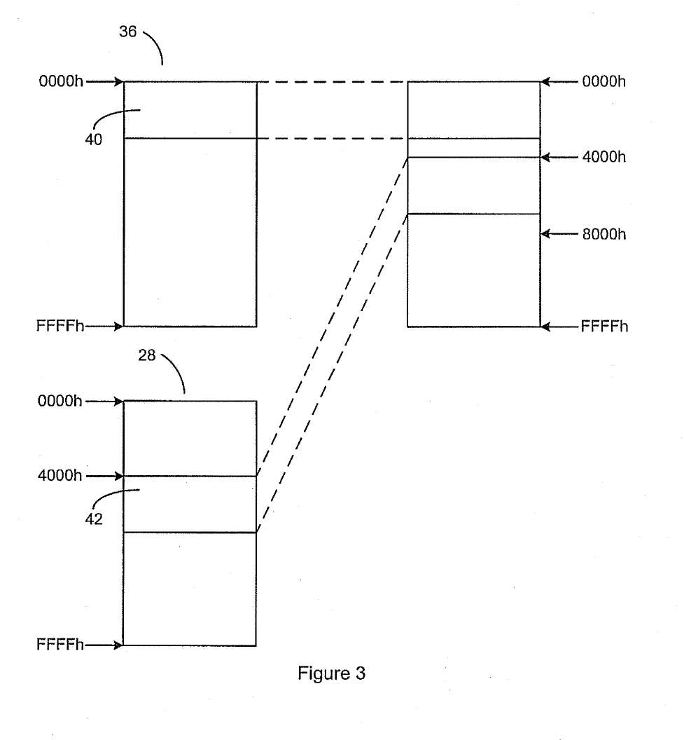

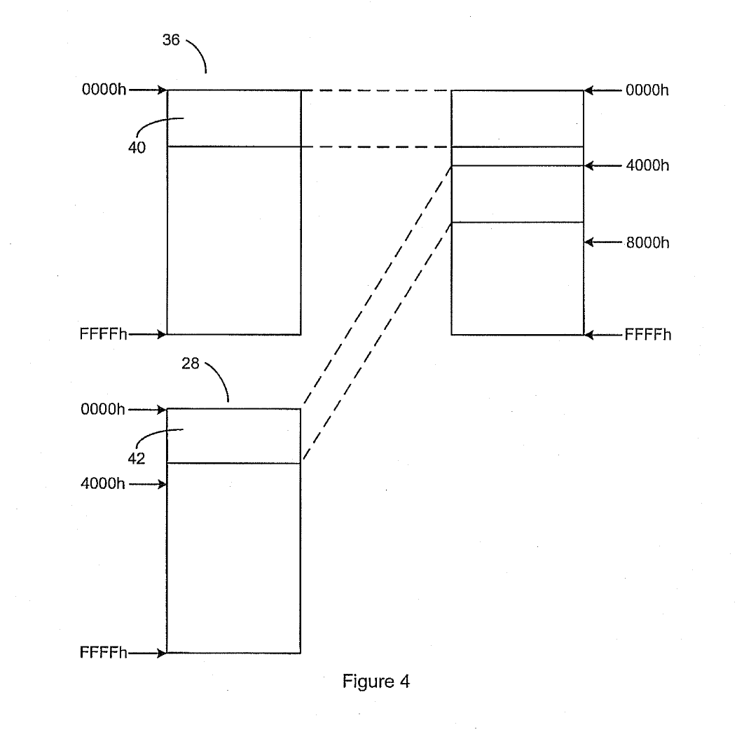

In certain embodiments, the translation block 26 may also perform register address translation on the received control signals if they are intended for the parent IC die 19. These functions will be described in greater detail with reference to FIGS. 3 and 4.

The translation block 26 may further receive signals from the child IC die 20 (via the bridge control interface 30) and translate them as necessary before passing them to the control interface 24 and to the controller 12 or other component of the apparatus 10.

The (possibly translated) control signals are passed from the translation block 26 to the bridge control interface 30, and from there to the control interface 34 of the child IC die 20. This occurs regardless of whether the control signals are intended for the parent IC die 19 or the child IC die 20, in order to reduce the latency of signals sent to the child IC die. That is, it is generally desirable that signals to the SiP 18 should be actioned as quickly as possible. However, signals to the child IC die 20 must pass through the parent IC die 19, as described above, adding latency.

In order to reduce this latency, according to embodiments of the invention, all received control signals are forwarded to the child IC die, prior to the translation block 26 determining the IC die for which the control signal is intended. In embodiments employing bus protocols with device addresses, therefore, the device address parts of the received control signals are translated as described above, and the signals forwarded to the child IC die 20. It may be that no register address translation is necessary for control signals to the child IC die 20, as will be described with reference to FIGS. 3 and 4.

The control interface 34 receives the control signals from the bridge control interface 30, and uses them to access the registers 36 of the child IC die.

If it is later determined that the control signal was not intended for the child IC die 20, a number of possible actions may be performed, depending on the chosen implementation. In one embodiment, the translation block 26 instructs the bridge control interface 30 to issue an interrupt signal to the child IC die 20, terminating its access of the registers 36, for example while the incoming data is still in a holding register before actually writing to the actual storage register 36. In another embodiment, the translation block 26 may instruct the bridge control interface 30 to ignore any signals received from the child IC die 20 in response to the forwarded control signal. In other embodiments, the control signal may not be understood by the child IC die 20, or may be recognised as outside the register address range of the child IC die 20, which therefore may not respond. In these embodiments, further action is unnecessary to halt the operation of the child IC die 20 in response to the forwarded control signal.

Level shift circuitry 32 may be employed to alter the voltage level of the control signals in the event that the voltage requirements of the parent IC die 19 and the child IC die 20 differ.

If the control signal is not intended for the child IC die 20, then it is intended for the parent IC die 19. In these instances, the register address part may be translated by the translation block 26 and used to access the registers 28 of the parent IC die. It may be that the register address is translated according to the requirements of the parent die for all incoming signals, before being input to any decision circuitry in the translation block. If the translated address is valid for the parent die, the registers 28 of the parent IC die may be written to immediately.

FIG. 3 shows the registers 36, 28 of the child slave IC die 20 and the parent slave IC die 19, respectively, according to one embodiment of the present invention.

The child die registers 36 comprise a register address space 40 beginning at the address 0000h and ending before the address 4000h. The parent die registers 28 comprises a register address space 42 beginning at the address 4000h, that is, the register address space 42 of the parent die is offset with respect to the register address space 40 of the child die, and that offset is such that no overlap of the two address spaces 40, 42 occurs, i.e. the addresses do not overlap. This offset allows the combination of the two register banks 28, 36 (as shown on the right of FIG. 3) to be uniquely addressable by circuitry outside the SiP 18. That is, a composite register address space (i.e. a total number of addresses,) is defined that is the combination of the two individual register address spaces 40, 42.

As mentioned above, no register address translation is necessary for accesses to the child die registers 36, as the child register address space 40 begins at 0000h in both the composite register address space (visible to circuitry external to the SiP 18) and the child die 20 itself. Moreover, as the parent register address space 42 is offset within the parent IC die 19, no register address translation is necessary in this embodiment for accesses to the parent registers 28 either. That is to say, the addresses of the composite register address space are all individually unique and directly addressable as seen from outside the SiP.

FIG. 4 shows an alternative embodiment in which the register address spaces 40, 42 overlap.

As with the previous embodiment, the register address space 40 of the child die begins at 0000h and ends before 4000h. However, within the parent die 19, the register address space 42 of the parent die also begins at 0000h. Therefore, in this embodiment the register address spaces 40, 42 overlap, i.e. the addresses do overlap, and register address translation is necessary so that both register banks are uniquely addressable by circuitry external to the SiP 18.

In this embodiment, the child register address space 40 is not translated, such that no register address translation is required for signals intended for the child IC die 20. This helps minimise latency, an advantage in systems where bus timing constraints are particularly tight. When the child register address space 40 is not translated, the parent register address space 42 is translated so that it begins at 4000h, i.e. so that it is offset and no overlap occurs between the two register address spaces 40, 42 for circuitry external to the SiP 18. Thus, the addresses of the child register address space 40 and the parent register address space 42 in this alternative embodiment are not all individually unique and directly addressable. However, by means of translating at least one of the child register address space 40 or the parent register address space 42, all of the addresses of the composite register address space in this alternative embodiment are again addressable as seen from outside the SiP.

It should be apparent to those skilled in the art that the register sizes, offsets and address spaces are dependent on the implementation, and no limitation is to be implied by the register sizes, address spaces or precise offsets disclosed herein. For example, FIGS. 3 and 4 show a space, i.e. gap, between the register address spaces 40, 42 in the composite register address space. However, by setting the offset such that it is equal to the size of the child register address space, the space may be reduced or removed completely.

Both the parent registers 28 and the child registers 36 are therefore made uniquely addressable by circuitry external to the SiP 18, either by offsetting the address space 42 of the parent registers 28, i.e. directly addressable, or by translating the address space 42 so that it appears offset to external circuitry, i.e. indirectly addressable.

In the majority of the description above, the parent IC die 19 and the child IC die 20 are depicted side-by-side for clarity. Indeed, this is one possible configuration of the dies in the SiP 18. However, in order to reduce the footprint of the SiP 18, the IC dies 19, 20 may be stacked on top of one another, possibly separated by an insulating spacer. In one embodiment, the parent IC die 19 and child IC die 20 may be directly connected by wire bonds between them. In another embodiment, the parent IC die 19 and child IC die 20 may be mounted on an internal printed circuit board (PCB), each separately bonded to lands on the PCB with a track running between the bonds. In a further embodiment, the parent IC die 19 and child IC die 20 may be mounted directly on top of one another, with the “bottom” die face down, mounted on conducting balls on a PCB. The “top” die, also face down, may be mounted on conducting balls to lands on the backside of the “bottom” die. The top die may then be connected to the front side of the bottom die via “through silicon vias” or tracks to some of the balls connecting the bottom die to the PCB. Any arrangement of the parent and child die(s) is contemplated by the present invention.

Also not illustrated is the housing of both dies 19, 20. In one embodiment, both dies 19, 20 may be surrounded by a single, common housing, i.e. a single “package”. However, the present invention is also applicable to so-called “package-on-package” arrangements, where each die is surrounded by its own housing, and connection is between dies are formed between terminals of the respective housings.

Although FIG. 2 and the description illustrate and describe a SiP 18 with just two dies, i.e. a parent die 19 and a child die 20, it will also be apparent to those skilled in the art that the present invention is extendible to SiPs comprising more than two dies.

For example, in a SiP comprising three dies, the first IC die may act as a parent die as described above; the second and third IC dies may act as child dies, with the second and third IC dies connected in parallel to the first. Further dies may be added to the package in a similar manner.

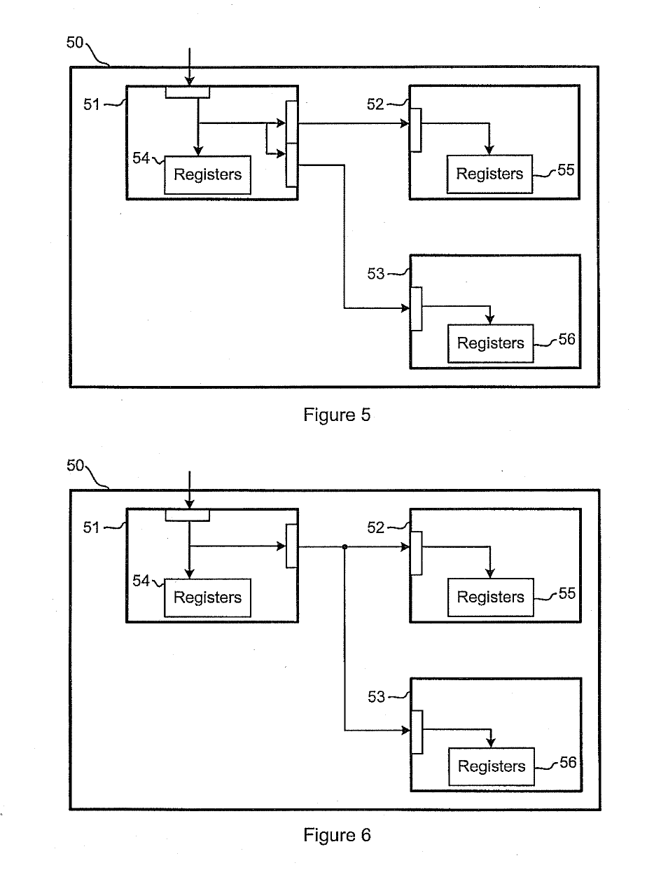

FIG. 5 shows a SiP 50 comprising three IC dies 51, 52, 53. Each IC die comprises a respective bank of registers 54, 55, 56. Further circuitry is not shown for clarity. However, the function of the three IC dies may be readily understood by reference to FIG. 2. In this embodiment, the first IC die 51 operates as the parent IC die, and comprises separate interface circuitry for connecting to each of the second IC die 52 and the third IC die 53, which are coupled in parallel as child IC dies. In operation, the parent IC die 51 receives control signals from a controller or a processor, and forwards the control signals to both the child IC dies 52, 53. The provision of separate interfaces in the parent IC die for each of the child IC dies allows level shift circuitry in each interface to apply different voltage shifts to the control signals, if necessary.

FIG. 6 shows a SiP 50 that is similar to that described with respect to the FIG. 5. However, in this embodiment the parent IC die 51 comprises only a single interface, and the signals are propagated to the child IC dies 52, 53 by a coupling outside the parent IC die.

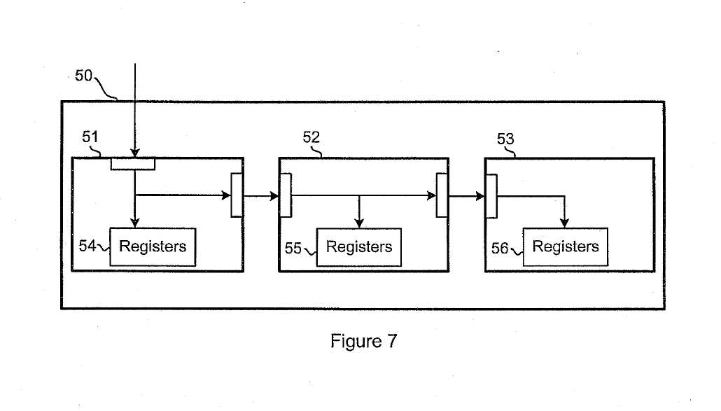

FIG. 7 shows a SiP 50 according to a further embodiment, where the first IC die 51 acts as a parent IC die. The second IC die 52 is coupled to the first IC die 51, and the third IC die 53 is coupled to the second IC die 52. That is, the three IC dies 51, 52, 53 are connected in series. The second IC die 52 in this embodiment therefore also acts as a parent IC die, and requires the necessary circuitry (e.g. translation block, bridge control interface) as shown in FIG. 2. The third IC die 53 acts as a child IC die.

The register address translation in embodiments with more than two IC dies follows similar principles to those described with respect to FIGS. 3 and 4. However, register address translation is necessary for at least one of the child IC dies in the examples of FIGS. 5 and 6. That is, these arrangements have two child IC dies which, according to the principles described above, have register address spaces that both start at 0000h. Therefore, translation of the register address part of one of the register address spaces is required so that no overlap occurs between respective child register address spaces.

For example, say that the register address spaces of both child register banks 55, 56 start at 0000h, and the register address space of the parent register bank 54 starts at 8000h. In that instance, the composite register address space of the SiP 50 must cover all three register address spaces. The register address space of the second IC die register bank 55, say, may be translated so that it starts at 4000h. Thus, control signals received by the first IC die 51 may comprise a register address part in the range of 0000h to CFFFh (or higher). If they are in the range 8000h to CFFFh, the control signals are intended for the parent IC die 51. If they are in the range 0000h to 3FFFh, the control signals are intended for the third IC die 53. If they are in the range 4000h to 7FFFh, the control signals are intended for the second IC die 52, and must be translated to the range 0000h to 3FFFh before being forwarded to the second IC die 52.

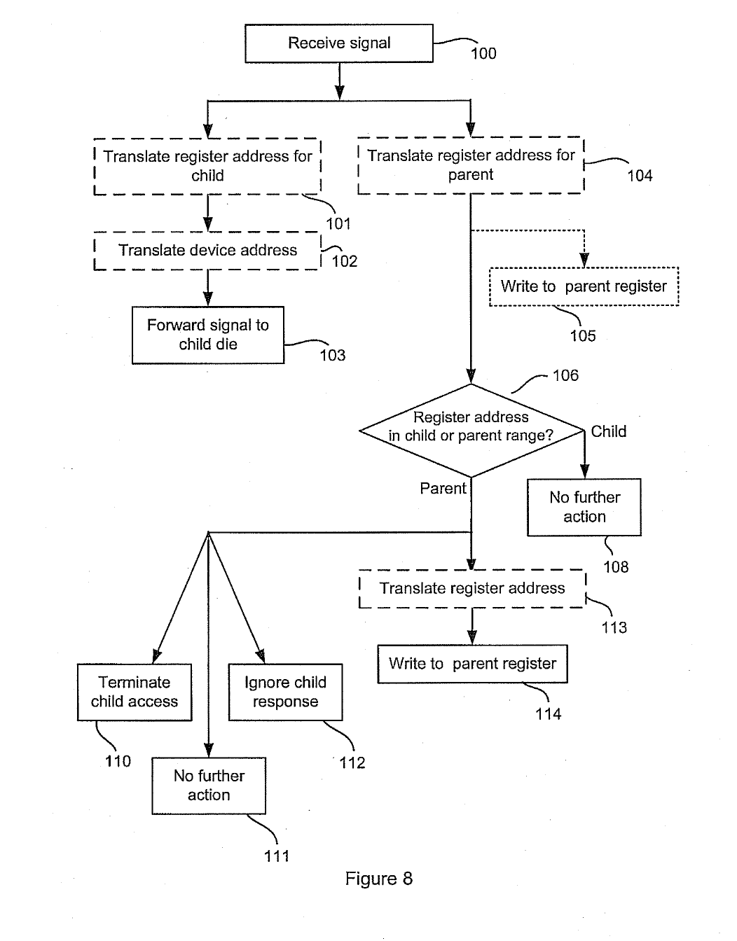

FIG. 8 is a flowchart of a method in accordance with embodiments of the present invention, performed in the parent IC die 19.

The method begins in step 100 when a signal, for example a control signal, is received from outside the SiP 18, i.e. over the pins 22. The control signal comprises a register address part that addresses a composite register address space, for example as shown in FIGS. 3 and 4.

The flowchart comprises two branches that may be performed in parallel or in sequence: a forwarding action (i.e. forwarding the signal to the child IC die), and a processing action (i.e. interpreting the signal within the parent IC die, or using it to access a register address in the parent IC die 19).

In step 101, the parent IC die 19 optionally may perform register address translation on the register address part of the received control signal for forwarding to the child IC die. For example, this may occur if the SiP comprises more than one child IC die, which therefore have overlapping register address spaces as described above. Alternatively, the child register address space may require translation because it overlaps with the parent register address space.

Optionally, if the signal is received using a bus protocol that uses device addresses, the parent IC die 19 performs device address translation in step 102. That is, the received signal specifies a device address that is the SiP address, and the parent IC die replaces this address with that of the child IC die 20. If the signal is received using a bus protocol that does not use device addresses, step 102 is not performed.

In step 103, the signal is forwarded to the child IC die 20, via the bridge control interface 30. Thus, it can be seen that this step occurs regardless of whether the signal is for the child IC die or the parent IC die.

In parallel with steps 101, 102 and 103 above, in one embodiment the parent IC die 19 may optionally translate the register address part of the received control signal for the parent IC die (step 104). Such a translation may involve shifting one or more of the register address bits, or flipping one or more of the register address bits, for example.

Optionally, it may be possible at this stage to write to the parent register on the basis of the (possibly translated) received control signal in step 105. That is, in this embodiment it is not necessary to determine whether the control signal is intended for the parent IC die or the child IC die. Rather, a write to the parent register may be performed regardless; if the write fails (i.e. because the composite address space register address received in step 100 was in the child area of the composite address space and so is—possibly after translation step 104—outside the physical address space of the parent die), it is implicit that the control signal was intended for the child IC die.

In step 106, the parent IC die (e.g. in the translation block 26) determines whether the (possibly translated) received signal is intended for the parent IC die 19 or the child IC die 20. In one embodiment, it may do this by determining whether the register address specified in the signal (either before or after translation) is within the range of the parent register address space, that is, using the examples of FIGS. 3 and 4, whether or not the specified address is equal to or greater than 4000h. Again using the examples of FIGS. 3 and 4, if the register address has been translated in step 104, it is determined whether the translated address is in the range of 0000h to 3FFFh (the child address space being similarly translated in step 104 by e.g. inverting the bit corresponding to 4000h so that it does not fall within this range).

If the specified address is not within the parent register address space, no further action is necessary within the parent IC die (step 108), as the signal has already been forwarded to the child IC die in step 103, which will use the signal to access its registers 36.

If the specified address is within the parent register address space, the parent IC die may terminate the access to the child IC die, for example by issuing an interrupt signal (step 110), ignore any response from the child IC die (step 112), or take no action with regard to the child IC die. This latter embodiment may occur, for example, if the child IC die does not respond due to the specified register address being out of its range. The parent IC die also uses the signal to access its own registers 28 (step 114). It may be necessary to translate the register address (step 113) before accessing the parent registers 28, if this has not already been done in step 104, and if an overlap exists between the child register address space and the parent register address space, as shown in FIG. 4.

The translation of the address data in the control signal, being typically just the inversion of one or two of the more significant bits in the address, can happen on-the-fly, without adding appreciable delay to the data signal, and thus not violating any timing constraints on the data interface. However, the detection of which chip the control data is destined for may not be apparent until at least some of the address has already been received and transmitted. Further, the action required may not be evident until the full control data word is received and transmitted. Thus it is desirable to allow the full data word to be transmitted to the child IC die 20, rather than confuse it with incomplete data, before generating some interrupt or other action as appropriate.

The present invention therefore provides a convenient scheme for combining two or more IC dies together such that a single interface is presented to external circuitry to which they are connected. Moreover, the scheme is such that each of the IC dies may be employed both within the SiP and on its own within an electronic system. The child IC die in particular requires no modification to operate as part of the combination or on its own.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. An integrated circuit combination, comprising:
a first integrated circuit die comprising at least a first interface for at least receiving control signals, a second interface and a first control register bank;
a second integrated circuit die comprising at least a third interface, coupled to said second interface, and a second control register bank; and
a signal path, within said combination, coupling said first interface to said first control register bank and to said second control register bank via said second and third interfaces.

2. An integrated circuit combination as claimed in claim 1, wherein the first control register bank has a first register address space, and wherein the second control register bank has a second register address space, and wherein said control signals have at least a register address part addressing a composite register address space having a number of addresses equal to at least a number of addresses in said first and second register address spaces.

3. An integrated circuit combination as claimed in claim 2, wherein the first integrated circuit die comprises decision circuitry for determining on the basis of said register address part whether the control signal is for the first integrated circuit die or the second integrated circuit die.

4. An integrated circuit combination as claimed in claim 3, wherein the decision circuitry is configured to determine whether the control signal is for the first integrated circuit die or the second integrated circuit die based on whether or not the register address part lies within a predetermined range.

5. An integrated circuit combination as claimed in claim 2, wherein said first register address space is offset with respect to said second register address space, such that said first register address space does not overlap said second register address space.

6. An integrated circuit combination as claimed in claim 2, wherein said first register address space at least partially overlaps said second register address space, said first integrated circuit die further comprising register address translation circuitry for adapting the register address part of said control signals.

7. An integrated circuit combination as claimed in claim 1, wherein the control signals further comprise a device address part, and wherein the first integrated circuit die further comprises device address translation circuitry configured to translate said device address part from an address of the integrated circuit combination to an address of the second integrated circuit die.

8. An integrated circuit combination as claimed in claim 1, wherein the first integrated circuit die is configured to forward said control signals to said second integrated circuit die, regardless of whether or not said control signals are for the second integrated circuit die.

9. An integrated circuit combination as claimed in claim 1, further comprising:
at least a third integrated circuit die, comprising at least a third control register bank.

10. An integrated circuit combination as claimed in claim 9, wherein the third integrated circuit die is coupled to the first integrated circuit die.

11. An integrated circuit combination as claimed in claim 9, wherein the third integrated circuit die is coupled to the second integrated circuit die.

12. An integrated circuit combination as claimed in claim 1, wherein the first integrated circuit die is a power management device.

13. An integrated circuit combination as claimed in claim 1, wherein the second integrated circuit die is an audio codec device.

14. An integrated circuit, suitable for use as the first integrated circuit die in claim 1.

15. An apparatus comprising an integrated circuit combination according to claim 1.

16. An apparatus according to claim 15 wherein the apparatus is a portable electronic device.

17. An apparatus according to claim 16 wherein the apparatus is at least one of: a computing device; a laptop; a notebook computer; a PDA; a media player; an MP3 player; a video player; a portable television device; a communication device; a mobile telephone; a mobile email device; a GPS device or a navigation device.

18. A method in an integrated circuit die, the integrated circuit die connected to a further integrated circuit die as part of an integrated circuit combination, the method comprising:
receiving a control signal; and
forwarding the control signal to the further integrated circuit die regardless of whether or not the control signal was intended for the further integrated circuit die.

19. A method as claimed in claim 18, wherein the integrated circuit die comprises a first control register bank having a first register address space, and the further integrated circuit die comprises a second control register bank having a second register address space, the control signal comprising at least a register address part addressing a composite register address space comprising at least said first and second register address spaces.

20. A method as claimed in claim 19, further comprising:
determining from the register address part whether or not the control signal was intended for the further integrated circuit die.

21. An integrated circuit combination, comprising:
a first integrated circuit, comprising a first register bank having a first register address space, a first interface for receiving control signals, and a second interface; and
a second integrated circuit, comprising a second register bank having a second register address space, and a third interface coupled to said second interface;
wherein said control signals comprise at least a register address part for addressing a composite register address space comprising at least said first and second register address spaces.
